(19) United States
(12) Patent Application Publication
(10) Pub. No.: US 2024/0263067 A1
(43) Pub. Date: Aug. 8, 2024

(54) SEMICONDUCTOR NANOPARTICLE COMPLEX, SEMICONDUCTOR NANOPARTICLE COMPLEX COMPOSITION, SEMICONDUCTOR NANOPARTICLE COMPLEX CURED MEMBRANE, SEMICONDUCTOR NANOPARTICLE COMPLEX DISPERSION LIQUID, METHOD FOR PRODUCING SEMICONDUCTOR NANOPARTICLE COMPLEX COMPOSITION, AND METHOD FOR PRODUCING SEMICONDUCTOR NANOPARTICLE COMPLEX CURED MEMBRANE

(71) Applicant: SHOEI CHEMICAL INC., Tokyo (JP)

(72) Inventors: Makoto KIDO, Tosu-shi (JP); Hirokazu SASAKI, Tosu-shi (JP)

(21) Appl. No.: 18/608,736

(22) Filed: Mar. 18, 2024

Related U.S. Application Data
(63) Continuation of application No. 17/595,927, filed on Nov. 29, 2021, now abandoned.

(30) Foreign Application Priority Data
May 31, 2019 (JP) 2019-103241
May 31, 2019 (JP) 2019-103242

(51) Int. Cl. C09K 11/02; B82Y 20/00; B82Y 40/00; C09K 11/08; C09K 11/70; H01L 33/50

(52) U.S. Cl. CPC C09K 11/025; C09K 11/0883; C09K 11/70; C09K 11/703; B82Y 20/00; B82Y 40/00; H01L 33/502

(57) ABSTRACT

Provided is a semiconductor nanoparticle complex having both improved fluorescence quantum yield and improved heat resistance. A semiconductor nanoparticle complex according to an embodiment includes a semiconductor nanoparticle complex in which two or more ligands including a ligand I and a ligand II are coordinated to the surface of a semiconductor nanoparticle, wherein: the ligands are composed of an organic group and a coordinating group, the ligand I has one mercapto group as the coordinating group, and the ligand II has at least two or more mercapto groups as the coordinating groups.

### CROSS REFERENCE TO RELATED APPLICATIONS

This application is a continuation of U.S. Non-Provisional patent application Ser. No. 17/595,927, filed 29 Nov. 2021, which claims priority Patent Cooperation Treaty Application Number PCT/JP2020/021465 field on 29 May 2020, which claims priority to Japanese Patent Application 2019-103241 filed 31 May 2019 and to Japanese Patent Application 2019-103242 filed 31 May 2019, the entirety of each of which is hereby incorporated herein by reference for all purposes.

### TECHNICAL FIELD

The present invention relates to a semiconductor nanoparticle complex, semiconductor nanoparticle complex composition, semiconductor nanoparticle complex cured membrane, semiconductor nanoparticle complex dispersion liquid, method for producing semiconductor nanoparticle complex composition, and method for producing semiconductor nanoparticle complex cured membrane.

### BACKGROUND ART

Semiconductor nanoparticles that are so small that a quantum confinement effect is exhibited have a bandgap that depends on the particle diameter. Excitons formed in semiconductor nanoparticles by means of photoexcitation, charge injection, and the like, emit photons with energy corresponding to the band gap by recombination, hence, light emission at a desired wavelength can be obtained by appropriately selecting the composition of the semiconductor nanoparticles and particle diameter thereof.

At the early stage of the research, semiconductor nanoparticles were mainly studied for elements including Cd and Pb, but since Cd and Pb are substances subject to regulation by the Restriction of the Use of Certain Hazardous Substances, in recent years, research on non-Pb-based and non-Cd-based semiconductor nanoparticles has been carried out.

Attempts have been made to use semiconductor nanoparticles in a variety of applications such as display applications, biomarking applications, and solar cell applications. In particular, in display applications, the use of semiconductor nanoparticles formed into a membrane as a wavelength conversion layer has begun.

### CITATION LIST

[PTL 1] Japanese Patent Application Publication No. 2013-136498.
[PTL 2] International Publication No. 2017/038487.

### Non Patent Literature

[NPL 1] Takashi Kami, “Semiconductor quantum dots: their synthesis and application to bioscience”, Production and Technology, Vol. 63, No. 2, p. 58-63, 2011.
[NPL 2] Fabien Dubois et al., “A Versatile Strategy for Quantum Dot Ligand Exchange” J. AM. CHEM. SOC Vol. 129, No. 3, p. 482-483, 2007.
[NPL 3] Boon-Kin Pong et al., “Modified Ligand-Exchange for Efficient Solubilization of CdSe/ZnS Quantum Dots in Water: A Procedure Guided by Computational Studies” Langmuir Vol. 24, No. 10, p. 5270-5276, 2008.
[NPL 4] Samsulida Abd. Rahman et al, “Thiolate-Capped CdSe/ZnS Core-Shell Quantum Dots for the Sensitive Detection of Glucose” Sensors Vol. 17, No. 7, p. 1537, 2017.
[NPL 5] Whitney Nowak Wenger et al, “Functionalization of Cadmium Selenide Quantum Dots with Poly(ethylene glycol): Ligand Exchange, Surface Coverage, and Dispersion Stability” Langmuir, Vol. 33, No. 33, pp. 8239-8245, 2017.

### SUMMARY OF INVENTION

Semiconductor nanoparticles are generally dispersed in a dispersion medium, and prepared as a semiconductor nanoparticle dispersion liquid to be used in various fields.

With semiconductor nanoparticles alone, the dispersion medium suitable for dispersion is limited by the surface state of the semiconductor nanoparticles. Therefore, by coordinating a ligand to the surface of the semiconductor nanoparticle, it is possible to disperse the nanoparticles in a dispersion medium required for application in each field.

Non-Patent Literature 1 to 5 and Patent Literature 1 disclose that a dispersion medium suitable for dispersion can be changed by exchanging a ligand to be coordinated to the surface of the semiconductor nanoparticles with a different ligand.

Further, Patent Literature 2 discloses a semiconductor nanoparticle complex having a high fluorescence quantum yield and high emission stability against ultraviolet rays and the like in which a ligand having a carboxyl group and a ligand having a mercapto group are used as the ligands, and both ligands are coordinated to the surface of semiconductor nanoparticles.

In a semiconductor nanoparticle complex, a binding force between the semiconductor nanoparticle and the ligand differs depending on the type of coordinating group of the ligand. Where a ligand having a weak binding force is coordinated to a semiconductor nanoparticle, when the semiconductor nanoparticle complex is dispersed in a dispersion medium, the ligand having a weak binding force to the semiconductor nanoparticle is detached from the semiconductor nanoparticle, resulting in a reduced fluorescence quantum yield.

Further, depending on the application, in a process including a step of forming a film of a semiconductor nanoparticle complex, a step of baking a photoresist including a semiconductor nanoparticle complex, a solvent removal and resin curing step after inkjet patterning a semiconductor nanoparticle complex, or the like, the semiconductor nanoparticle complex may be exposed to a high temperature of about 200° C. in the presence of oxygen. At that time, the ligand having a weak binding force to the semiconductor nanoparticles, such as mentioned hereinabove, is more likely to be detached from the surface of the semiconductor nanoparticles, which causes a decrease in fluorescence quantum yield.

The present inventors have investigated the semiconductor nanoparticle complex described in Patent Literature 2 for the purpose of improving the fluorescence quantum yield of the semiconductor nanoparticle complex and improving the stability of the fluorescence quantum yield when the complex is exposed to a high temperature (hereinafter referred to as “heat resistance” in the present application), and it was clarified that the heat resistance of the semiconductor nanoparticle complex was low.

Therefore, an object of the present invention is to provide a semiconductor nanoparticle complex having both improved fluorescence quantum yield and improved heat resistance.

The semiconductor nanoparticle complex according to the present invention is a semiconductor nanoparticle complex in which two or more ligands including a ligand I and a ligand II are coordinated to the surface of a semiconductor nanoparticle, wherein
the ligands are composed of an organic group and a coordinating group;
the ligand I has one mercapto group as the coordinating group; and
the ligand II has at least two or more mercapto groups as the coordinating groups.

In the present application, the range indicated by preposition “to” includes the numbers indicated at both ends thereof.

According to the present invention, it is possible to provide a semiconductor nanoparticle complex having both improved fluorescence quantum yield and improved heat resistance.

### DETAILED DESCRIPTION

As a result of diligent studies carried out to resolve the above problems, the present inventors have found that a semiconductor nanoparticle complex having high fluorescence quantum yield and high heat resistance can be obtained by appropriately selecting the type of ligand. Furthermore, it was found that a dispersion liquid containing a semiconductor nanoparticle complex at a high mass fraction can be obtained. That is, one aspect of the present invention resides in a semiconductor nanoparticle complex composed of a semiconductor nanoparticle and ligands coordinated to the surface of the semiconductor nanoparticle, a semiconductor nanoparticle complex composition including the semiconductor nanoparticle complex, and a semiconductor nanoparticle complex cured membrane. Further, another aspect of the present invention resides in a semiconductor nanoparticle complex dispersion liquid in which a semiconductor nanoparticle complex composed of a semiconductor nanoparticle and ligands coordinated to the surface of the semiconductor nanoparticle is dispersed in a dispersion medium, a method for producing a semiconductor nanoparticle complex composition using the semiconductor nanoparticle complex dispersion liquid and a method for producing a semiconductor nanoparticle complex cured membrane.

In the present invention, the semiconductor nanoparticle complex is a semiconductor nanoparticle complex having light emission characteristics. The semiconductor nanoparticle complex of the present invention is a particle that absorbs light of 340 nm to 480 nm and emits light having an emission peak wavelength of 400 nm to 750 nm.

The full width at half maximum (FWHM) of the emission spectrum of the semiconductor nanoparticle complex is preferably 40 nm or less. The full width at half maximum of the emission spectrum is more preferably 38 nm or less, and further preferably 35 nm or less, for the reason that color mixing can be prevented when the semiconductor nanoparticle complex is applied to a display or the like.

The fluorescence quantum yield (QY) of the semiconductor nanoparticle complex is preferably 70% or more. Since color conversion can be performed more efficiently when the fluorescence quantum yield is 70% or more, the fluorescence quantum yield is more preferably 75% or more, and further preferably 80% or more. In the present invention, the fluorescence quantum yield of the semiconductor nanoparticle complex can be measured using a quantum yield measurement system.

### —Semiconductor Nanoparticle—

A semiconductor nanoparticle constituting the semiconductor nanoparticle complex is not particularly limited as long as the above-mentioned fluorescence quantum yield and light emission characteristics such as full width at half maximum are satisfied, and may be a particle made of one type of semiconductor or a particle composed of two or more different semiconductors. In the case of particles composed of two or more different types of semiconductors, a core-shell structure may be composed of these semiconductors. For example, the particle may be of a core-shell type having a core including a Group III element and a Group V element and a shell including a Group II element and a Group VI element covering at least a part of the core. Here, the shell may have a plurality of shells having different compositions, or may have one or more gradient-type shells in which the ratio of elements constituting the shell changes in the shell.

Specific examples of Group III elements include In, Al and Ga.

Specific examples of Group V elements include P, N and As.

The composition for forming the core is not particularly limited, but InP is preferable from the viewpoint of light emission characteristics.

The Group II element is not particularly limited, and examples thereof include Zn and Mg.

Examples of Group VI elements include S, Se, Te and O.

The composition for forming the shell is not particularly limited, but from the viewpoint of the quantum confinement effect, ZnS, ZnSe, ZnSeS, ZnTeS, ZnTeSe, and the like are preferable. In particular, when a Zn element is present on the surface of the semiconductor nanoparticle, the effect of the present invention can be exerted to a greater extent.

When the nanoparticle has a plurality of shells, it is sufficient that at least one shell having the above-mentioned composition be included. Further, in the case of a gradient type shell in which the ratio of elements constituting the shell changes in the shell, the shell does not necessarily have to have the composition according to the composition notation.

Here, in the present invention, whether the shell covers at least a part of the core and the element distribution inside the shell can be confirmed by composition analysis by, for example, energy dispersive X-ray spectroscopy (TEM-EDX) using a transmission electron microscope.

The average particle diameter of the semiconductor nanoparticles is preferably 10 nm or less, and more preferably 7 nm or less. In the present invention, the average particle diameter of semiconductor nanoparticles can be measured by calculating the particle diameter of 10 or more particles by an area equivalent diameter (Heywood diameter) in a particle image observed using a transmission electron microscope (TEM). From the viewpoint of light emission characteristics, a narrow particle diameter distribution is preferable, and a coefficient of variation is preferably 15% or less. Here, the coefficient of variation is defined as “coefficient of variation=(standard deviation of particle diameter)/(average particle diameter)”. The coefficient of variation of 15% or less indicates that semiconductor nanoparticles having a narrower particle diameter distribution are obtained.

### —Ligand—

In the present invention, in a semiconductor nanoparticle complex, a ligand is coordinated to the surface of the semiconductor nanoparticle. The coordination mentioned herein means that the ligand chemically affects the surface of the semiconductor nanoparticle. The ligand may be bonded to the surface of the semiconductor nanoparticle by coordination bonding or in any other bonding mode (for example, by covalent bond, ionic bond, hydrogen bond, and the like), or when the ligand is present on at least a portion of the surface of the semiconductor nanoparticle, the ligand does not necessarily have to form a bond.

In the present invention, the ligand is composed of a coordinating group coordinated to a semiconductor nanoparticle and an organic group.

Of the ligands that form the semiconductor nanoparticle complex by coordinating to the semiconductor nanoparticle, at least one is a ligand I having one mercapto group as a coordinating group, and at least one is a ligand II having at least two or more mercapto groups as coordinating groups.

The mercapto groups of ligand I and ligand II strongly coordinate to the shell of the semiconductor nanoparticle, fill in the defective parts of the semiconductor nanoparticle, prevent deterioration of the emission characteristics of the semiconductor nanoparticle, and contribute to improving heat resistance. When Zn is present on the surface of the semiconductor nanoparticle, the above-mentioned effects can be enhanced by the strength of the bonding force between the mercapto group and Zn.

The organic group of the ligand I is preferably a monovalent hydrocarbon group which may have a substituent or a hetero group. Such a structure enables dispersion in various dispersion media as compared with the case where an inorganic ligand is coordinated.

Although not particularly limited, the ligand I is preferably an alkylthiol. In particular, from the viewpoint of heat resistance, an alkyl thiol having an alkyl group having 6 to 14 carbon atoms is preferable, and hexanethiol, octanethiol, decanethiol, and dodecanethiol are more preferable.

The organic group of the ligand II is preferably a divalent or higher hydrocarbon group which may have a substituent or a hetero group. With this structure, the dispersibility in a dispersion medium is improved, the dispersion in various dispersion media becomes possible, and the heat resistance is further improved.

Each mercapto group of the ligand II is preferably present via not more than 5 carbon atoms. From the viewpoint of preventing a crosslinking reaction between the semiconductor nanoparticles, it is more preferable that each mercapto group be present via not more than three carbon atoms.

Since the ligand II has at least two or more mercapto groups, one molecule of the ligand II can strongly coordinate to a plurality of locations on the surface of the semiconductor nanoparticle. However, the density of the ligand near the surface of the semiconductor nanoparticle decreases, which may cause a decrease in heat resistance. In the semiconductor nanoparticle complex of the present invention, by coordinating the ligand II together with the ligand I, it is possible to prevent a decrease in the density of the ligand near the surface of the semiconductor nanoparticle and increase the heat resistance.

Since the ligand II has at least two or more mercapto groups, one molecule of the ligand II can strongly coordinate to a plurality of locations on the surface of the semiconductor nanoparticle. As a result, the heat resistance of the semiconductor nanoparticle complex is improved. Further, the amount of the ligand in the semiconductor nanoparticle complex is reduced as compared with the monovalent ligand, and dispersion in a dispersion medium at a high mass fraction is enabled. However, the density of the ligand near the surface of the semiconductor nanoparticle decreases, which may cause a decrease in heat resistance. Therefore, by coordinating the ligand II together with the ligand I, the decrease in the density of the ligand near the surface of the semiconductor nanoparticles can be prevented and the heat resistance can be improved. By coordinating both ligand I and ligand II, it is possible not only to adjust the dispersibility of the semiconductor nanoparticle complex, but also to enable dispersion in a dispersion medium at a high mass fraction.

The mass ratio of ligand I to ligand II (ligand I/ligand II) is preferably 0.2 to 1.5. From the viewpoint of improving the heat resistance and adjusting the dispersibility described above, the mass ratio is more preferably 0.3 to 1.0.

In the semiconductor nanoparticle complex, the mass ratio of the ligands to the semiconductor nanoparticle (ligands/semiconductor nanoparticle) is preferably 0.05 or more and 0.60 or less. When the ratio is 0.05 or more, the surface of the semiconductor nanoparticle can be sufficiently covered with the ligands, the light emission characteristics of the semiconductor nanoparticles are not deteriorated, and the dispersibility in a dispersion liquid, a composition, and a cured membrane can be enhanced. Further, when the ratio is 0.60 or less, an increase in the size and volume of the semiconductor nanoparticle complex can be easily suppressed, and the mass fraction when the complex is dispersed in a dispersion liquid, a composition, or a cured membrane can be easily increased. In the semiconductor nanoparticle complex, the mass ratio of the ligands to the semiconductor nanoparticle (ligands/semiconductor nanoparticle) is more preferably 0.15 or more and 0.35 or less.

The molecular weight of each of the ligands is preferably 50 or more and 600 or less, and more preferably 450 or less.

When the molecular weight of the ligand is 50 or more, the surface of the semiconductor nanoparticle can be sufficiently covered with the ligand, the light emission characteristics of the semiconductor nanoparticles are not deteriorated, and the dispersibility in a dispersion liquid, a composition, or a cured membrane can be increased. Further, when the molecular weight of the ligand is 600 or less, an increase in the size and volume of the semiconductor nanoparticle complex can be suppressed, and the mass fraction when the complex is dispersed in a dispersion liquid, a composition, or a cured membrane can be easily increased.

A ligand other than the ligand I and the ligand II may be coordinated to the surface of the semiconductor nanoparticle. When a ligand other than the ligand I and the ligand II is coordinated, the total mass fraction of the ligand I and the ligand II to all ligands is preferably 0.7 or more. Within this range, as described above, it is possible to improve the heat resistance while making it possible to adjust the dispersibility.

Further, where a ligand other than the ligand I and the ligand II is coordinated to the surface of the semiconductor nanoparticle, the molecular weight of the ligand other than the ligand I and the ligand II is preferably 50 or more and 600 or less, and more preferably 450 or less.

### (Method for Producing Semiconductor Nanoparticle Complex)

### —Method for Producing Semiconductor Nanoparticle—

The following is an example of a method for producing a semiconductor nanoparticle.

A core of a semiconductor nanoparticle can be formed by heating a precursor mixture obtained by mixing a Group III precursor, a Group V precursor, and, if necessary, an additive in a solvent.

Examples of the solvent include, but are not limited to, 1-octadecene, hexadecane, squalene, oleylamine, trioctylphosphine, trioctylphosphine oxide, and the like.

Examples of Group III precursors include, but are not limited to, acetates, carboxylates, halides, and the like containing the Group III elements.

Examples of Group V precursors include, but are not limited to, organic compounds and gases containing the Group V elements. Where the precursor is a gas, a core can be formed by reacting while injecting a gas into a precursor mixture including components other than the gas.

The semiconductor nanoparticle may contain one or more elements other than those of Groups III and V as long as the effects of the present invention are not impaired, in which case a precursor of such element(s) can be added at the time of core formation.

Examples of the additive include, but are not limited to, carboxylic acids, amines, thiols, phosphines, phosphine oxides, phosphinic acids, and phosphonic acids as dispersants. The dispersant can also serve as a solvent.

After forming the core of the semiconductor nanoparticles, the emission characteristics of the semiconductor nanoparticles can be improved by adding a halide as needed.

In one embodiment, an In precursor and, if necessary, a metal precursor solution obtained by adding a dispersant to a solvent are mixed under vacuum and heated once at 100° C. to 300° C. for 6 h to 24 h, followed by the addition of a P precursor, heating at 200° C. to 400° C. for 3 min to 60 min, and then cooling. Further, by adding a halogen precursor and heat-treating at 25° C. to 300° C., preferably 100° C. to 300° C., and more preferably 150° C. to 280° C., a core particle dispersion liquid including core particles can be obtained.

As a result of adding a shell-forming precursor to the synthesized core particle dispersion liquid, semiconductor nanoparticles have a core-shell structure, and the quantum yield (QY) and stability can be improved.

The elements that constitute the shell are thought to have a structure such as an alloy, heterostructure, or amorphous structure on the surface of the core particles, but it is also conceivable that some of them have moved to the inside of the core particles due to diffusion.

The added shell-forming element is mainly present near the surface of the core particle and has a role of protecting the semiconductor nanoparticle from external factors. In the core-shell structure of the semiconductor nanoparticles, it is preferable that the shell covers at least a part of the core, and more preferably the entire surface of the core particle is uniformly covered.

In one embodiment, a Zn precursor and a Se precursor are added to the above-described core particle dispersion liquid, then heating is performed at 150° C. to 300° C., more preferably 180° C. to 250° C., and then a Zn precursor and a S precursor are added, followed by heating at 200° C. to 400° C., and preferably 250° C. to 350° C. As a result, core-shell type semiconductor nanoparticles can be obtained.

Here, although not particularly limited, examples of suitable Zn precursors include carboxylates such as zinc acetate, zinc propionate and zinc myristate, halides such as zinc chloride and zinc bromide, and organic salts such as diethyl zinc.

Examples of suitable Se precursors include phosphine selenides such as tributylphosphine selenide, trioctylphosphine selenide and tris(trimethylsilyl)phosphine selenide, selenols such as benzeneselenol and selenocysteine, and selenium/octadecene solutions.

Examples of suitable S precursors include phosphine sulfides such as tributylphosphine sulfide, trioctylphosphine sulfide and tris(trimethylsilyl)phosphine sulfide, thiols such as octanethiol, dodecanethiol and octadecanethiol, and sulfur/octadecene solutions.

The precursors of the shell may be mixed in advance and added once or in multiple times, or each may be added separately once or in multiple times. When the shell precursors are added in multiple times, heating by changing the temperature may be performed after each shell precursor is added.

In the present invention, a method for producing semiconductor nanoparticles is not particularly limited, and in addition to the methods shown above, conventional methods such as a hot injection method, a uniform solvent method, a reverse micelle method, and a CVD method can be used, or any other method may be adopted.

### —Method for Producing Semiconductor Nanoparticle Complex—

A semiconductor nanoparticle complex can be produced by coordinating the above ligands to the semiconductor nanoparticle produced as described above.

A method for coordinating a ligand to a semiconductor nanoparticle is not limited, and a ligand exchange method using the coordinating force of the ligand can be used. Specifically, semiconductor nanoparticles in which the organic compound used in the process of producing the semiconductor nanoparticles described above is coordinated to the surface of the semiconductor nanoparticles are brought into contact with the target ligand in a liquid phase, thereby making it possible to obtain a semiconductor nanoparticle complex in which the target ligand is coordinated to the surface of the semiconductor nanoparticle. In this case, a liquid-phase reaction using a solvent as described hereinbelow is usually carried out, but when the ligand to be used is a liquid under the reaction conditions, a reaction mode is possible in which the ligand itself is used as a solvent and no other solvent is added.

Further, where a purification step and a redispersion step, such as described hereinbelow, are performed before the ligand exchange, the ligand exchange can be easily performed.

As another method, a method of adding a ligand and reacting the ligand with a precursor at the time of forming semiconductor nanoparticles can also be used. When the semiconductor nanoparticle has a core-shell structure, the ligand may be added to either the core precursor or the shell precursor.

In one embodiment, the desired semiconductor nanoparticle complex can be obtained by purifying and redispersing the semiconductor nanoparticle-containing dispersion liquid after the semiconductor nanoparticles have been produced, then adding a solvent including the ligand I and the ligand II, and stirring for 1 min to 120 min at a temperature of 50° C. to 200° C. in a nitrogen atmosphere.

The semiconductor nanoparticle complex can be purified as follows.

In one embodiment, the semiconductor nanoparticle complex can be precipitated from the dispersion liquid by adding a polarity-changing solvent such as acetone. The precipitated semiconductor nanoparticle complex can be collected by filtration or centrifugation, while supernatant containing unreacted starting materials and other impurities may be discarded or reused. The precipitated semiconductor nanoparticle complex can then be washed with additional dispersion medium and dispersed again. This purification process can be repeated, for example, 2 to 4 times, or until the desired purity is achieved.

In the present invention, the method for purifying the semiconductor nanoparticle complex is not particularly limited, and in addition to the methods shown above, for example, flocculation, liquid-liquid extraction, distillation, electrodeposition, size-selection chromatography and/or ultrafiltration, and the like may be used.

These purification methods can be used for the purpose of facilitating the ligand exchange of semiconductor nanoparticles even before the above-mentioned ligand exchange.

The ligand composition in the semiconductor nanoparticle complex can be quantified using 1H-NMR. The obtained semiconductor nanoparticles are dispersed in a deuterated solvent, and electromagnetic waves are applied in a magnetic field to cause 1H nuclear magnetic resonance. A free induction decay signal obtained at this time is Fourier-analyzed to obtain a 1H-NMR spectrum. The 1H-NMR spectrum gives a characteristic signal at a position corresponding to the structure of the ligand species. The composition of the target ligand is calculated from the position of these signals and the integrated intensity ratio. Examples of the deuterated solvent include CDCl₃, acetone-d6, N-hexane-D14, and the like.

The optical characteristics of the semiconductor nanoparticle complex can be measured using a fluorescence quantum yield measurement system (for example, Otsuka Electronics Co., Ltd., QE-2100). The obtained semiconductor nanoparticle complex is dispersed in a dispersion liquid, and excitation light is used to obtain an emission spectrum. The fluorescence quantum yield (QY) and full width at half maximum (FWHM) were calculated from the emission spectrum after re-excitation correction in which a re-excitation fluorescence emission spectrum corresponding to fluorescence emission by re-excitation was excluded from the emission spectrum obtained herein. Examples of the dispersion liquid include normal hexane, toluene, acetone, PGMEA and octadecene.

The heat resistance of the semiconductor nanoparticle complex is evaluated using dry powder. The dispersion medium is removed from the purified semiconductor nanoparticle complex, and heating is performed in air at 180° C. for 5 h in a state of dry powder. After the heat treatment, the semiconductor nanoparticle complex is redispersed in the dispersion liquid, and the reexcitation-corrected fluorescence quantum yield (=QYb) is measured. Assuming that the fluorescence quantum yield before heating is “QYa”, the rate of change in the fluorescence quantum yield before and after the heat treatment can be calculated by the following (Formula 1).

$$\{ 1 - ( QYb / QYa ) \} \times 100 \qquad ( Formula 1 )$$

The heat resistance can be calculated by the following (Formula 2).

$$( QYb / QYa ) \times 100 \qquad ( Formula 2 )$$

That is, the fact that the rate of change between the fluorescence quantum yield before heating and the fluorescence quantum yield after heating is less than 10% indicates that the heat resistance is 90% or more.

Where the heat resistance is 90% or more, the decrease in fluorescence quantum yield can be suppressed even after passing through the process involving a step of forming the semiconductor nanoparticle complex into a film, a step of baking a photoresist containing the semiconductor nanoparticles, or a step of removing a solvent and curing a resin after inkjet patterning of semiconductor nanoparticles.

### (Semiconductor Nanoparticle Complex Dispersion Liquid)

The semiconductor nanoparticle complex contained in the semiconductor nanoparticle complex dispersion liquid of the present invention can adopt the above-mentioned configuration of the semiconductor nanoparticle complex of the present invention. In the present invention, the state in which the semiconductor nanoparticle complex is dispersed in the dispersion medium represents a state in which the semiconductor nanoparticle complex does not precipitate or a state in which the semiconductor nanoparticle complex does not remain creating visible turbidity (cloudiness) when the semiconductor nanoparticle complex and the dispersion medium are mixed. A liquid obtained by dispersing the semiconductor nanoparticle complex in a dispersion medium is referred to as a semiconductor nanoparticle complex dispersion liquid.

By setting the above-mentioned mass ratio of the ligand I to the ligand II, it is possible to disperse the semiconductor nanoparticle complex so that the mass fraction of the semiconductor nanoparticles is 20% by mass or more in at least one of hexane, acetone, propylene glycol monomethyl ether acetate (PGMEA), propylene glycol monomethyl ether (PGME), isobornyl acrylate (IBOA), ethanol, methanol, and a mixture composed of any combination of compounds from this group as a dispersion medium. By dispersing in these dispersion media, the resulting dispersion liquid can be used for dispersing in a cured membrane or resin described hereinbelow while maintaining the dispersibility of the semiconductor nanoparticle complex.

In the semiconductor nanoparticle complex dispersion liquid of the present invention in which the semiconductor nanoparticle complex of the present invention is dispersed, the semiconductor nanoparticle complex is dispersed at a high mass fraction, and as a result, the mass fraction of the semiconductor nanoparticles in the semiconductor nanoparticle complex liquid can be 20% by mass or more, further 25% by mass or more, further 30% by mass or more, and further 35% by mass or more.

### (Semiconductor Nanoparticle Complex Composition)

In the present invention, a monomer or a prepolymer can be selected as the dispersion medium of the semiconductor nanoparticle complex dispersion liquid to form a semiconductor nanoparticle complex composition.

The monomer or prepolymer is not particularly limited, and examples thereof include radically polymerizable compounds including an ethylenically unsaturated bond, siloxane compounds, epoxy compounds, isocyanate compounds, and phenol derivatives.

From the viewpoint of enabling the selection from a wide range of applications for the semiconductor nanoparticle complex, acrylic monomers are preferable. In particular, examples of acrylic monomers that can be selected according to the application of the semiconductor nanoparticle complex include lauryl acrylate, isodecyl acrylate, stearyl acrylate, isobornyl acrylate, 3,5,5-trimethylcyclohexanol acrylate, 1,6-hexadiol diacrylate, cyclohexadimethanol diacrylate, tricyclodecanedimethanol diacrylate, polyethylene glycol diacrylate, trimethylolpropane triacrylate, tris(2-hydroxyethyl)isocyanurate triacrylate, pentaerythritol tetraacrylate, ditrimethylolpropane acrylate, dipentaerythritol hexaacrylate, and the like.

Further, a crosslinking agent may be added to the semiconductor nanoparticle complex composition.

Depending on the type of monomer in the semiconductor nanoparticle complex composition, the crosslinking agent may be selected from a polyfunctional (meth)acrylate, a polyfunctional silane compound, a polyfunctional amine, a polyfunctional carboxylic acid, a polyfunctional thiol, a polyfunctional alcohol, and a polyfunctional isocyanate.

Further, the semiconductor nanoparticle complex composition can further include various organic solvents that do not affect curing, such as aliphatic hydrocarbons such as pentane, hexane, cyclohexane, isohexane, heptane, octane, and petroleum ether, alcohols, ketones, esters, glycol ethers and glycol ether esters, aromatic hydrocarbons such as benzene, toluene, xylene and mineral spirits, and alkyl halides such as dichloromethane and chloroform. The above-mentioned organic solvent can be used not only for diluting the semiconductor nanoparticle complex composition but also as a dispersion medium. That is, it is also possible to disperse the semiconductor nanoparticle complex of the present invention in the above-mentioned organic solvent to obtain a semiconductor nanoparticle complex dispersion liquid.

Further, the semiconductor nanoparticle complex composition may include an appropriate initiator, scattering agent, catalyst, binder, surfactant, adhesion promoter, antioxidant, UV absorber, anti-aggregation agent, a dispersant, and the like depending on the type of monomer in the semiconductor nanoparticle complex composition.

Further, in order to improve the optical characteristics of the semiconductor nanoparticle complex composition or the semiconductor nanoparticle complex cured membrane described hereinbelow, the semiconductor nanoparticle complex composition may include a scattering agent. The scattering agent is a metal oxide such as titanium oxide or zinc oxide, and the particle diameter thereof is preferably 100 nm to 500 nm. From the viewpoint of the effect of scattering, the particle diameter of the scattering agent is more preferably 200 nm to 400 nm. By including the scattering agent, the absorbance is improved by a factor of about twice. The amount of the scattering agent is preferably 2% by mass to 30% by mass, and more preferably 5% by mass to 20% by mass from the viewpoint of maintaining the patterning property of the composition.

Depending on the configuration of the semiconductor nanoparticle complex of the present invention, the content of the semiconductor nanoparticle complex in the semiconductor nanoparticle complex composition can be 20% by mass or more. By setting the mass fraction of the semiconductor nanoparticles in the semiconductor nanoparticle complex composition to 30% by mass to 95% by mass, the semiconductor nanoparticle complex and the semiconductor nanoparticles can be dispersed at a high mass fraction in the cured membrane described hereinbelow.

When the semiconductor nanoparticle complex composition of the present invention is formed into a membrane having a thickness of 10 μm, the absorbance of the membrane with respect to light having a wavelength of 450 nm from the normal direction is preferably 1.0 or more, more preferably 1.3 or more. And even more preferably 1.5 or more. As a result, the light from the backlight can be efficiently absorbed, so that the thickness of the cured membrane described hereinbelow can be reduced, and the device using the membrane can be miniaturized.

### (Diluted Composition)

The diluted composition is obtained by diluting the above-described semiconductor nanoparticle complex composition of the present invention with an organic solvent.

The organic solvent for diluting the semiconductor nanoparticle complex composition is not particularly limited, and examples thereof include aliphatic hydrocarbons such as pentane, hexane, cyclohexane, isohexane, heptane, octane, and petroleum ether, alcohols, ketones, esters, glycol ethers, glycol ether esters, aromatic hydrocarbons such as benzene, toluene, xylene and mineral spirit, and alkyl halides such as dichloromethane and chloroform. Among these, glycol ethers and glycol ether esters are preferable from the viewpoint of solubility in a wide range of resins and membrane uniformity at the time of coating.

### (Semiconductor Nanoparticle Complex Cured Membrane)

In the present invention, the semiconductor nanoparticle complex cured membrane is a membrane that includes a semiconductor nanoparticle complex and has been cured. The semiconductor nanoparticle complex cured membrane can be obtained by curing the above-mentioned semiconductor nanoparticle complex composition or diluted composition into a membrane.

The semiconductor nanoparticle complex cured membrane includes semiconductor nanoparticles, ligands coordinated to the surface of the semiconductor nanoparticles, and a polymer matrix.

The polymer matrix is not particularly limited, and examples thereof include (meth)acrylic resins, silicone resins, epoxy resins, silicone resins, maleic acid resins, butyral resins, polyester resins, melamine resins, phenol resins, and polyurethane resins. A semiconductor nanoparticle complex cured membrane may be obtained by curing the semiconductor nanoparticle complex composition described above. The semiconductor nanoparticle complex cured membrane may further include a crosslinking agent.

A method for curing the membrane is not particularly limited, and the membrane can be cured by a curing method suitable for the composition constituting the membrane, such as heat treatment and ultraviolet treatment.

The semiconductor nanoparticle and the ligand coordinated to the surface of the semiconductor nanoparticle, which are included in the semiconductor nanoparticle complex cured membrane, preferably constitute the above-described semiconductor nanoparticle complex. By configuring the semiconductor nanoparticle complex contained in the semiconductor nanoparticle complex cured membrane of the present invention as described above, the semiconductor nanoparticle complex can be dispersed in the cured membrane at a higher mass fraction. As a result, the mass fraction of the semiconductor nanoparticles in the semiconductor nanoparticle complex cured membrane can be 20% by mass or more, and further 40% by mass or more. However, when this mass fraction is 70% by mass or more, the amount of composition that will constitute the membrane is reduced, and it becomes difficult to cure and form the membrane.

Since the semiconductor nanoparticle complex cured membrane of the present invention includes the semiconductor nanoparticle complex at a high mass fraction, the absorbance of the semiconductor nanoparticle complex cured membrane can be increased. When the semiconductor nanoparticle complex cured membrane has a thickness of 10 μm, the absorbance with respect to light having a wavelength of 450 nm from the normal direction of the semiconductor nanoparticle complex cured membrane is preferably 1.0 or more, more preferably 1.3 or more, and even more preferably 1.5 or more.

Further, since the semiconductor nanoparticle complex cured membrane of the present invention includes a semiconductor nanoparticle complex having high light emission characteristics, it is possible to provide a semiconductor nanoparticle complex cured membrane having high light emission characteristics. The fluorescence quantum yield of the semiconductor nanoparticle complex cured membrane is preferably 70% or more, and more preferably 80% or more.

The thickness of the semiconductor nanoparticle complex cured membrane is preferably 50 μm or less, more preferably 20 μm or less, and even more preferably 10 μm or less in order to miniaturize the device in which the semiconductor nanoparticle complex cured membrane is to be used.

### (Semiconductor Nanoparticle Complex Patterning Membrane and Display Element)

A semiconductor nanoparticle complex patterning membrane can be obtained by forming the above-described semiconductor nanoparticle complex composition or diluted composition into a membrane-shaped pattern. The method for patterning the semiconductor nanoparticle complex composition and the diluted composition is not particularly limited, and examples thereof include spin coating, bar coating, inkjet, screen printing, and photolithography.

The display element uses the above-mentioned semiconductor nanoparticle complex patterning membrane. For example, by using a semiconductor nanoparticle complex patterning membrane as a wavelength conversion layer, it is possible to provide a display element having excellent fluorescence quantum yield.

The semiconductor nanoparticle complex of the present invention has the following configuration.

(1) A semiconductor nanoparticle complex in which two or more ligands including a ligand I and a ligand II are coordinated to the surface of a semiconductor nanoparticle, wherein
the ligands are composed of an organic group and a coordinating group;
the ligand I has one mercapto group as the coordinating group; and
the ligand II has at least two or more mercapto groups as the coordinating groups.

(2) The semiconductor nanoparticle complex dispersion liquid as described in (1) hereinabove, wherein the mass ratio of the ligand I to the ligand II (ligand I/ligand II) is 0.2 to 1.5.

(3) The semiconductor nanoparticle complex as described in (1) or (2) hereinabove, wherein the mass ratio of the ligands to the semiconductor nanoparticle (ligands/semiconductor nanoparticle) is 0.60 or less.

(4) The semiconductor nanoparticle complex as described in any one of (1) to (3) hereinabove, wherein the mass ratio of the ligands to the semiconductor nanoparticle (ligands/semiconductor nanoparticle) is 0.35 or less.

(5) The semiconductor nanoparticle complex as described in any one of (1) to (4) hereinabove, wherein the molecular weight of the ligand is 600 or less.

(6) The semiconductor nanoparticle complex as described in any one of (1) to (5) hereinabove, wherein the molecular weight of the ligand is 450 or less.

(7) The semiconductor nanoparticle complex as described in any one of (1) to (6) hereinabove, wherein the total mass fraction of the ligand I and the ligand II in the ligands is 0.7 or more.

(8) The semiconductor nanoparticle complex as described in any one of (1) to (7) hereinabove, wherein each mercapto group of the ligand II is present via not more than five carbon atoms.

(9) The semiconductor nanoparticle complex as described in any one of (1) to (8) hereinabove, wherein each mercapto group of the ligand II is present via not more than three carbon atoms.

(10) The semiconductor nanoparticle complex as described in any one of (1) to (9) hereinabove, wherein the organic group of the ligand II is a divalent or higher hydrocarbon group that may have a substituent or a hetero atom.

(11) The semiconductor nanoparticle complex as described in any one of (1) to (10) hereinabove, wherein the organic group of the ligand I is a monovalent hydrocarbon group which may have a substituent or a hetero atom.

(12) The semiconductor nanoparticle complex as described in any one of (1) to (11) hereinabove, wherein the ligand I is an alkylthiol.

(13) The semiconductor nanoparticle complex as described in any one of (1) to (12) hereinabove, wherein the ligand I is a thiol having an alkyl group having 6 to 14 carbon atoms.

(14) The semiconductor nanoparticle complex as described in any one of (1) to (13) hereinabove, wherein the ligand I is at least one selected from the group consisting of hexanethiol, octanethiol, decanethiol, and dodecanethiol.

(15) The semiconductor nanoparticle complex as described in any one of (1) to (14) hereinabove, wherein the semiconductor nanoparticle complex can be dispersed in at least one of hexane, acetone, PGMEA, PGME, IBOA, ethanol, methanol and a mixture thereof, and can be dispersed so that the mass fraction of the semiconductor nanoparticles is 25% by mass or more.

(16) The semiconductor nanoparticle complex as described in any one of (1) to (15) hereinabove, wherein the semiconductor nanoparticle complex can be dispersed in at least one of hexane, acetone, PGMEA, PGME, IBOA, ethanol, methanol and a mixture thereof, and can be dispersed so that the mass fraction of the semiconductor nanoparticles is 35% by mass or more.

(17) The semiconductor nanoparticle complex as described in any one of (1) to (16) hereinabove, wherein a fluorescence quantum yield of the semiconductor nanoparticle complex is 70% or more.

(18) The semiconductor nanoparticle complex as described in any one of (1) to (17) hereinabove, wherein a full width at half maximum of emission spectrum of the semiconductor nanoparticle complex is 40 nm or less.

(19) The semiconductor nanoparticle complex as described in any one of (1) to (18) hereinabove, wherein the semiconductor nanoparticle includes In and P.

(20) The semiconductor nanoparticle complex as described in any one of (1) to (19) hereinabove, wherein a surface composition of the semiconductor nanoparticles includes Zn.

(21) The semiconductor nanoparticle complex as described in any one of (1) to (20) hereinabove, wherein when the semiconductor nanoparticle complex is heated in air at 180° C. for 5 h, a rate of change between the fluorescence quantum yield before heating and the fluorescence quantum yield after heating is 10% or less.

The semiconductor nanoparticle complex composition of the present invention has the following constitution.

(22) A semiconductor nanoparticle complex composition in which the semiconductor nanoparticle complex as described in any one of (1) to (21) above is dispersed in a dispersion medium, wherein
the dispersion medium is a monomer or a prepolymer.

A semiconductor nanoparticle complex cured membrane of the present invention has the following configuration.

(23) A semiconductor nanoparticle complex cured membrane in which the semiconductor nanoparticle complex as described in any one of (1) to (21) hereinabove is dispersed in a polymer matrix.

The semiconductor nanoparticle complex dispersion liquid of the present invention has the following configuration.

<1> A semiconductor nanoparticle complex dispersion liquid in which a semiconductor nanoparticle complex in which two or more ligands are coordinated to the surface of a semiconductor nanoparticle is dispersed in a dispersion medium, wherein
the ligands include a ligand I and a ligand II each composed of an organic group and a coordinating group;
the ligand I has one mercapto group as the coordinating group; and
the ligand II has at least two or more mercapto groups as the coordinating groups.

<2> The semiconductor nanoparticle complex dispersion liquid as described in <1> hereinabove, wherein the dispersion medium is an organic dispersion medium.

<3> The semiconductor nanoparticle complex dispersion liquid as described in <1> or <2> hereinabove, wherein the mass ratio of the ligand I to the ligand II (ligand I/ligand II) is 0.2 to 1.5.

<4> The semiconductor nanoparticle complex dispersion liquid as described in any one of <1> to <3> hereinabove, wherein the mass ratio of the ligands to the semiconductor nanoparticle (ligands/semiconductor nanoparticle) is 0.60 or less.

<5> The semiconductor nanoparticle complex dispersion liquid as described in any one of <1> to <4> hereinabove, wherein the mass ratio of the ligands to the semiconductor nanoparticle (ligands/semiconductor nanoparticle) is 0.35 or less.

<6> The semiconductor nanoparticle complex dispersion liquid as described in any one of <1> to <5> hereinabove, wherein the total mass fraction of the ligand I and the ligand II in the ligands is 0.7 or more.

<7> The semiconductor nanoparticle complex dispersion liquid as described in any one of <1> to <6> hereinabove, wherein each mercapto group of the ligand II is present via not more than five carbon atoms.

<8> The semiconductor nanoparticle complex dispersion liquid as described in any one of <1> to <7> hereinabove, wherein each mercapto group of the ligand II is present via not more than three carbon atoms.

<9> The semiconductor nanoparticle complex dispersion liquid as described in any one of <1> to <8> hereinabove, wherein the organic group of the ligand II is a divalent or higher hydrocarbon group that may have a substituent or a hetero atom.

<10> The semiconductor nanoparticle complex dispersion liquid as described in any one of <1> to <9> hereinabove, wherein the organic group of the ligand I is a monovalent hydrocarbon group which may have a substituent or a hetero atom.

<11> The semiconductor nanoparticle complex dispersion liquid as described in any one of <1> to <10> hereinabove, wherein the molecular weight of the ligands is 600 or less.

<12> The semiconductor nanoparticle complex dispersion liquid as described in any one of <1> to <11> hereinabove, wherein the molecular weight of the ligands is 450 or less.

<13> The semiconductor nanoparticle complex dispersion liquid as described in any one of <1> to <12> hereinabove, wherein the ligand I is an alkylthiol.

<14> The semiconductor nanoparticle complex dispersion liquid as described in any one of <1> to <13> hereinabove, wherein the ligand I is a thiol having an alkyl group having 6 to 14 carbon atoms.

<15> The semiconductor nanoparticle complex dispersion liquid as described in any one of <1> to <14> hereinabove, wherein the ligand I is at least one selected from the group consisting of hexanethiol, octanethiol, decanethiol, and dodecanethiol.

<16> The semiconductor nanoparticle complex dispersion liquid as described in any one of <1> to <15> hereinabove, wherein
the organic group of the ligand II is an aliphatic hydrocarbon group having not more than 5 carbon atoms.

<17> The semiconductor nanoparticle complex dispersion liquid as described in any one of <1> to <16> hereinabove, wherein
the organic group of the ligand II is an aliphatic hydrocarbon group having not more than 3 carbon atoms.

<18> The semiconductor nanoparticle complex dispersion liquid as described in any one of <1> to <17> hereinabove, wherein
the dispersion medium is one dispersion medium or two or more mixed dispersion media selected from the group consisting of aliphatic hydrocarbons, alcohols, ketones, esters, glycol ethers, glycol ether esters, aromatic hydrocarbons, and alkyl halides.

<19> The semiconductor nanoparticle complex dispersion liquid as described in any one of <1> to <18> hereinabove, wherein
the dispersion medium is hexane, octane, acetone, PGMEA, PGME, IBOA, ethanol, methanol or a mixture thereof.

<20> The semiconductor nanoparticle complex dispersion liquid as described in any one of <1> to <19> hereinabove, wherein
a fluorescence quantum yield of the semiconductor nanoparticle complex is 70% or more.

<21> The semiconductor nanoparticle complex dispersion liquid as described in any one of <1> to <20> hereinabove, wherein
a full width at half maximum of emission spectrum of the semiconductor nanoparticle complex is 40 nm or less.

<22> The semiconductor nanoparticle complex dispersion liquid as described in any one of <1> to <21> hereinabove, wherein
the semiconductor nanoparticle includes In and P.

<23> The semiconductor nanoparticle complex dispersion liquid as described in any one of <1> to <22> hereinabove, wherein
a surface composition of the semiconductor nanoparticles includes Zn.

<24> The semiconductor nanoparticle complex dispersion liquid as described in any one of <1> to <23> hereinabove, wherein
the mass fraction of the semiconductor nanoparticles with respect to the semiconductor nanoparticle complex dispersion is 25% by mass or more.

<25> The semiconductor nanoparticle complex dispersion liquid as described in any one of <1> to <24> hereinabove, wherein
the mass fraction of the semiconductor nanoparticles with respect to the semiconductor nanoparticle complex dispersion is 35% by mass or more.

<26> The semiconductor nanoparticle complex dispersion liquid as described in any one of <1> to <25> hereinabove, wherein
when the semiconductor nanoparticle complex dispersion liquid is heated in air at 180° C. for 5 h, a rate of change between the fluorescence quantum yield before heating and the fluorescence quantum yield after heating is 10% or less.

<27> The semiconductor nanoparticle complex dispersion liquid as described in any one of <1> to <26> hereinabove, wherein
the organic dispersion medium is a monomer or a prepolymer.

A method for producing the semiconductor nanoparticle complex composition of the present invention has the following constitution.

<28> A method for producing a semiconductor nanoparticle complex composition comprising adding either one or both of a crosslinking agent and a dispersion medium to the semiconductor nanoparticle complex dispersion liquid as described in any one of <1> to <27> hereinabove.

A method for producing the semiconductor nanoparticle complex cured membrane of the present invention has the following configuration.

<29> A method for producing a semiconductor nanoparticle complex cured membrane, comprising curing a semiconductor nanoparticle complex composition obtained by the method for producing a semiconductor nanoparticle complex composition as described in <28> hereinabove.

The configurations and/or methods set forth in the present description are illustrated by way of example and can be changed in a variety of ways. Therefore, it can be understood that specific examples or embodiments thereof should not be considered to be limiting. The particular procedure or method set forth in the present description may represent one of a number of processing methods. Thus, various operations explained and/or described can be performed in the order explained and/or described, or can be omitted. Similarly, the order of the above methods can be changed.

The subject matter of the present disclosure is inclusive the various methods, systems and configurations disclosed in the present description, as well as any new and non-trivial combinations and secondary combinations of other features, functions, operations, and/or properties, as well as any equivalents thereof.

### EXAMPLES

Hereinafter, the present invention will be specifically described with reference to Examples and Comparative Examples, but the present invention is not limited thereto.

### Example 1

Semiconductor nanoparticles were synthesized according to the following method, and then a semiconductor nanoparticle complex was synthesized using the nanoparticles.

### (Synthesis of Semiconductor Nanoparticles)

### —Preparation of Precursors—

### ——Preparation of Zn Precursor Solution——

A total of 40 mmol of zinc oleate and 75 mL of octadecene were mixed and heated in vacuum at 110° C. for 1 h to prepare a Zn precursor of [Zn]=0.4 M.

### ——Preparation of Se Precursor (Trioctylphosphine Selenide)——

A total of 22 mmol of selenium powder and 10 mL of trioctylphosphine were mixed in nitrogen and stirred until complete dissolution to obtain trioctylphosphine selenide of [Se]=2.2 M.

### ——Preparation of S Precursor (Trioctylphosphine Sulfide) ——

A total of 22 mmol of sulfur powder and 10 mL of trioctylphosphine were mixed in nitrogen and stirred until complete dissolution to obtain trioctylphosphine sulfide of [S]=2.2 M.

### —Synthesis of Core—

Indium acetate (0.3 mmol) and zinc oleate (0.6 mmol) were added to a mixture of oleic acid (0.9 mmol), 1-dodecanethiol (0.1 mmol) and octadecene (10 mL), followed by heating to about 120° C. and reacting for 1 h under vacuum (<20 Pa). The mixture reacted under vacuum was placed in a nitrogen atmosphere at 25° C., tris(trimethylsilyl) phosphine (0.2 mmol) was added thereto, and then the mixture was heated to about 300° C. and reacted for 10 min. The reaction liquid was cooled to 25° C., octanoic chloride (0.45 mmol) was injected thereinto, and the reaction liquid was heated at about 250° C. for 30 min and then cooled to 25° C.

### —Synthesis of Shell—

Then, heating was performed to 200° C., and 0.75 mL of the Zn precursor solution and 0.3 mmol of trioctylphosphine selenide were added at the same time and reacted for 30 min to form a ZnSe shell on the surface of InP-based semiconductor nanoparticle. Further, 1.5 mL of the Zn precursor solution and 0.6 mmol of trioctylphosphine sulfide were added, the temperature was raised to 250° C., and the mixture was reacted for 1 h to form a ZnS shell.

### —Washing Step—

The reaction solution of the semiconductor nanoparticles obtained by the synthesis was added to acetone, mixed well, and then centrifuged. The centrifugal acceleration was 4000 G. The precipitate was collected, and normal hexane was added to the precipitate to prepare a dispersion liquid. This operation was repeated several times to obtain purified semiconductor nanoparticles.

### (Synthesis of Semiconductor Nanoparticle Complex)

In preparing the semiconductor nanoparticle complex, the ligand was first synthesized as follows.

### —Synthesis of Dodecanedithiol—

A total of 15 g of 1,2-decanediol and 28.7 mL of triethylamine were placed in a flask and dissolved in 120 mL of THF (tetrahydrofuran). The solution was cooled to 0° C., and 16 mL of methanesulfonic acid chloride was gradually added dropwise under a nitrogen atmosphere, while taking care that the temperature of the reaction solution did not exceed 5° C. due to the heat of reaction. Then, the reaction solution was heated to room temperature and stirred for 2 h. This solution was extracted with a chloroform-water system to collect the organic phase. The obtained solution was concentrated by evaporation, and an oily intermediate was obtained with magnesium sulfate. This was transferred to another flask, and 100 mL of 1.3 M thiourea dioxane solution was added under a nitrogen atmosphere. After refluxing the solution for 2 h, 3.3 g of NaOH was added and the solution was refluxed for another 1.5 h. The reaction solution was cooled to room temperature, and a 1 M aqueous HCl solution was added to reach pH=7 to neutralize the reaction solution. The obtained solution was extracted with a chloroform-water system to obtain dodecanedithiol (DDD).

### —Preparation of Semiconductor Nanoparticle Complex—

A semiconductor nanoparticles—1-octadecene dispersion liquid was prepared in a flask by dispersing the purified semiconductor nanoparticles in 1-octadecene so as to obtain a mass ratio of the nanoparticles of 20% by mass. A total of 0.8 g of dodecanethiol (DDT) was added to 5.0 g of the prepared semiconductor nanoparticles—1-octadecene dispersion liquid, 3.2 g of (2,3-dimercaptopropyl) propionate was further added, and stirring was performed at 110° C. for 60 min under a nitrogen atmosphere, followed by cooling to 25° C. to obtain a reaction solution of the semiconductor nanoparticle complex.

### —Washing Step—

A total of 5.0 mL of toluene was added to the reaction solution to prepare a dispersion liquid. A total of 25 mL of ethanol and 25 mL of methanol were added to the obtained dispersion liquid, followed by centrifugation at 4000 G for 20 minutes. After centrifugation, the clear supernatant was removed and the precipitate was collected. This operation was repeated several times to obtain a purified semiconductor nanoparticle complex.

### (Optical Characteristics/Heat Resistance)

The optical characteristics of the semiconductor nanoparticle complex were measured using a fluorescence quantum yield measurement system (QE-2100, manufactured by Otsuka Electronics Co., Ltd.). The obtained semiconductor nanoparticle complex was dispersed in a dispersion liquid, and a single light of 450 nm was used as excitation light to obtain an emission spectrum. The fluorescence quantum yield (QY) and full width at half maximum (FWHM) were calculated from the emission spectrum after re-excitation correction in which a re-excitation fluorescence emission spectrum corresponding to fluorescence emission by reexcitation was excluded from the emission spectrum obtained herein. PGMEA was used as the dispersion medium here. For the semiconductor nanoparticle complex that did not disperse in PGMEA, normal hexane was used as the dispersion medium.

The heat resistance of the semiconductor nanoparticle complex was evaluated using dry powder. The solvent was removed from the purified semiconductor nanoparticle complex, and heating was performed in air at 180° C. for 5 h in a state of dry powder. After the heat treatment, the semiconductor nanoparticle complex was redispersed in the dispersion liquid, and the reexcitation-corrected fluorescence quantum yield (=QYb) was measured. Assuming that the fluorescence quantum yield before heating was “QYa”, the heat resistance was calculated by the following (Formula 3).

$$( QYb / QYa ) \times 100 \qquad ( Formula 3 )$$

### (Semiconductor Nanoparticle Complex Dispersion Liquid)

The purified semiconductor nanoparticle complex was heated to 550° C. by differential thermogravimetric analysis (DTA-TG), held for 5 min, and cooled. The residual mass after the analysis was taken as the mass of the semiconductor nanoparticles, and the mass ratio of the semiconductor nanoparticles to the semiconductor nanoparticle complex was confirmed from this value.

With reference to the mass ratio, IBOA was added to the semiconductor nanoparticle complex. The dispersion state was confirmed by changing the addition amount of IBOA and changing the mass ratio of the semiconductor nanoparticles in the dispersion liquid by 5% by mass from 50% by mass to 10% by mass. The mass fraction at which precipitation and turbidity were no longer observed was listed in the table as the mass fraction of semiconductor nanoparticles.

In Table 2, various organic dispersion media were added to the semiconductor nanoparticle complex so that the mass fraction of the semiconductor nanoparticles was 5% by mass, and the dispersion state was represented by yes when the nanoparticles were dispersed and by no when precipitation and turbidity were observed.

### Example 2

A semiconductor nanoparticle complex and a semiconductor nanoparticle complex dispersion liquid were prepared and characteristics thereof were evaluated in the same manner as in Example 1, except that the amount of dodecanethiol to be added was set to 1.6 g and the amount of (2,3-dimercaptopropyl) propionate was set to 2.4 g in the preparation of the semiconductor nanoparticle complex.

### Example 3

A semiconductor nanoparticle complex was prepared and characteristics thereof were evaluated in the same manner as in Example 1, except that the amount of dodecanethiol to be added was set to 2.4 g and the amount of (2,3-dimercaptopropyl) propionate was set to 1.6 g in the preparation of the semiconductor nanoparticle complex.

### Example 4

A semiconductor nanoparticle complex and a semiconductor nanoparticle complex dispersion liquid were prepared and characteristics thereof were evaluated in the same manner as in Example 1, except that the amount of dodecanethiol to be added was set to 1.6 g, (2,3-dimercaptopropyl) propionate was replaced with methyl dihydrolipoate and the amount thereof was set to 2.4 g in the preparation of the semiconductor nanoparticle complex.

Methyl dihydrolipoate was synthesized by the following method.

### —Synthesis of Methyl Dihydrolipoate—

A total of 2.1 g (10 mmol) of dihydrolipoic acid was dissolved in 20 mL (49 mmol) of methanol, and 0.2 mL of concentrated sulfuric acid was added. The solution was refluxed under a nitrogen atmosphere for 1 h. The reaction solution was diluted with chloroform, and the solution was extracted in the order of a 10% HCl aqueous solution, a 10% Na₂CO₃ aqueous solution, and a saturated NaCl aqueous solution to collect the organic phase. The organic phase was concentrated by evaporation and purified by column chromatography using a hexane-ethyl acetate mixed solvent as a developing solvent to obtain methyl dihydrolipoate.

### Example 5

A semiconductor nanoparticle complex and a semiconductor nanoparticle complex dispersion liquid were prepared and characteristics thereof were evaluated in the same manner as in Example 1, except that the amount of dodecanethiol to be added was set to 0.6 g, the amount of (2,3-dimercaptopropyl) propionate was set to 2.4 g, and 1.0 g of oleic acid was further added in the preparation of the semiconductor nanoparticle complex.

### Example 6

A semiconductor nanoparticle complex and a semiconductor nanoparticle complex dispersion liquid were prepared and characteristics thereof were evaluated in the same manner as in Example 1, except that the amount of dodecanethiol to be added was set to 0.4 g, the amount of (2,3-dimercaptopropyl) propionate was set to 2.0 g, and 1.6 g of oleic acid was further added in the preparation of the semiconductor nanoparticle complex.

### Example 7

A semiconductor nanoparticle complex and a semiconductor nanoparticle complex dispersion liquid were prepared and characteristics thereof were evaluated in the same manner as in Example 1, except that dodecanethiol to be added was replaced with N-tetradecanoyl-N-(2-mercaptoethyl) tetradecaneamide, the amount thereof was set to 1.6 g, and the amount of (2,3-dimercaptopropyl) propionate was set to 2.4 g in the preparation of the semiconductor nanoparticle complex.

N-tetradecanoyl-N-(2-mercaptoethyl) tetradecaneamide was synthesized by the following method.

### Synthesis of N-tetradecanoyl-N-(2-mercaptoethyl) tetradecaneamide

A total of 0.78 g (10 mmol) of 2-aminoethanethiol and 3.4 mL (24 mmol) were placed in a 100 mL round bottom flask and dissolved in 30 mL of dehydrated dichloromethane. The solution was cooled to 0° C., and 5.4 mL (20 mmol) of tetradecanoyl chloride was slowly added dropwise under a nitrogen atmosphere, while taking care that the temperature of the solution did not exceed 5° C. After completion of the dropping, the reaction solution was heated to room temperature and stirred for 2 h. The reaction solution was filtered and the filtrate was diluted with chloroform. The liquid was extracted in the order of a 10% HCl aqueous solution, a 10% Na₂CO₃ aqueous solution, and a saturated NaCl aqueous solution to collect the organic phase. The organic phase was concentrated by evaporation and then purified by column chromatography using a mixed solvent of hexane-ethyl acetate as a developing solvent to obtain N-tetradecanoyl-N-(2-mercaptoethyl) tetradecaneamide.

### Example 8

A semiconductor nanoparticle complex and a semiconductor nanoparticle complex dispersion liquid were prepared and characteristics thereof were evaluated in the same manner as in Example 1, except that the amount of dodecanethiol to be added was set to 1.6 g, (2,3-dimercaptopropyl) propionate was replaced with N,N-didecyl-6,8-disulfanyloctanamide, and the amount thereof was changed to 2.4 g in the preparation of the semiconductor nanoparticle complex.

N,N-didecyl-6,8-disulfanyloctanamide was synthesized by the following method.

### Synthesis of N,N-didecyl-6,8-disulfanyloctanamide

A total of 3.0 g (10 mmol) of didecylamine, 1.3 g (10 mmol) of 1-hydroxybenzotriazole, and 1.9 g (10 mmol) of 1-ethyl-3-(3-dimethylaminopropyl) carbodiimide hydrochloride were placed in a round bottom flask and dissolved in 30 mL of dehydrated dichloromethane. A total of 2.1 g (10 mmol) of dihydrolipoic acid was added thereto, and the mixture was stirred at room temperature for 1 h. The reaction solution was diluted with 100 mL of dichloromethane and extracted in the order of 10% HCl aqueous solution, 10% Na₂CO₃ aqueous solution, and saturated NaCl aqueous solution, and the organic phase was collected. The organic phase was concentrated by evaporation and then purified by column chromatography using a hexane-ethyl acetate mixed solvent as a developing solvent to obtain N,N-didecyl-6,8-disulfanyloctanamide.

### Example 9

A semiconductor nanoparticle complex and a semiconductor nanoparticle complex dispersion liquid were prepared and characteristics thereof were evaluated in the same manner as in Example 1, except that the amount of dodecanethiol to be added was set to 3.2 g and the amount of (2,3-dimercaptopropyl) propionate was set to 0.8 g in the preparation of the semiconductor nanoparticle complex.

### Example 10

A semiconductor nanoparticle complex and a semiconductor nanoparticle complex dispersion liquid were prepared and characteristics thereof were evaluated in the same manner as in Example 1, except that the amount of dodecanethiol to be added was set to 0.4 g and the amount of (2,3-dimercaptopropyl) propionate was set to 3.6 g in the preparation of the semiconductor nanoparticle complex.

### Example 11

A semiconductor nanoparticle complex and a semiconductor nanoparticle complex dispersion liquid were prepared and characteristics thereof were evaluated in the same manner as in Example 1, except that the ligand to be added was only dodecanethiol and the amount thereof was set to 4.0 g in the preparation of the semiconductor nanoparticle complex.

### Example 12

A semiconductor nanoparticle complex and a semiconductor nanoparticle complex dispersion liquid were prepared and characteristics thereof were evaluated in the same manner as in Example 1, except that the ligand to be added was only (2,3-dimercaptopropyl) propionate and the amount thereof was set to 1.6 g in the preparation of the semiconductor nanoparticle complex.

### Example 13

A semiconductor nanoparticle complex and a semiconductor nanoparticle complex dispersion liquid were prepared and characteristics thereof were evaluated in the same manner as in Example 1, except that the amount of dodecanethiol to be added was set to 1.6 g, (2,3-dimercaptopropyl) propionate was replaced with dodecenylsuccinic acid, and the amount thereof was set to 2.4 g in the preparation of the semiconductor nanoparticle complex.

### Example 14

A semiconductor nanoparticle complex and a semiconductor nanoparticle complex dispersion liquid were prepared and characteristics thereof were evaluated in the same manner as in Example 1, except that dodecanethiol to be added was replaced with oleic acid, the amount thereof was set to 1.6 g, and the amount of (2,3-dimercaptopropyl) propionate was set to 2.4 g in the preparation of the semiconductor nanoparticle complex.

### Example 15

A semiconductor nanoparticle complex and a semiconductor nanoparticle complex dispersion liquid were prepared and characteristics thereof were evaluated in the same manner as in Example 1, except that dodecanethiol to be added was replaced with oleic acid, the amount thereof was set to 1.6 g, (2,3-dimercaptopropyl) propionate was further replaced with dodecenylsuccinic acid, and the amount thereof was set to 2.4 g in the preparation of the semiconductor nanoparticle complex.

### Example 16

A semiconductor nanoparticle complex and a semiconductor nanoparticle complex dispersion liquid were prepared and characteristics thereof were evaluated in the same manner as in Example 1, except that the amount of dodecanethiol to be added was set to 2.0 g, (2,3-dimercaptopropyl) propionate was replaced with oleic acid, and the amount thereof was set to 2.0 g in the preparation of the semiconductor nanoparticle complex.

### Example 17

A semiconductor nanoparticle complex and a semiconductor nanoparticle complex dispersion liquid were prepared and characteristics thereof were evaluated in the same manner as in Example 1, except that dodecanethiol to be added was replaced with 3,6,9,12-tetraoxadecaneamine, the amount thereof was set to 2.0 g, and the amount of (2,3-dimercaptopropyl) propionate was set to 2.4 g in the preparation of the semiconductor nanoparticle complex.

The results of Examples 1 to 10 above are shown in Table 1-1, and the results of Examples 11 to 17 are shown in Table 1-2. The semiconductor nanoparticle complex preferably has a fluorescence quantum yield of 70% or more and a heat resistance of 10% or more.

The meanings of the abbreviations shown in Table 1-1 and Table 1-2 are as follows.
LI: ligand I
LII: ligand II
Other: ligands other than the ligand I and the ligand II
Total L: all ligands coordinated to semiconductor nanoparticle
QD: semiconductor nanoparticle (quantum dot)
sDDT: dodecanethiol

TABLE 1-1

| | Semiconductor nanoparticle complex | | | | | | | | |
|---|---|---|---|---|---|---|---|---|---|
| | Substance name | | | | | | | | |
| | Ligand I | Ligand II | | Molecular weight | | | Weight | | |
| | (L I) | (L II) | Other | L I | L II | Other | L I | L II | Other |
| Example | DDT | (2,3-dimercaptopropyl) | — | 202 | 234 | — | 20 | 80 | — |
| 1 | | propionate | | | | | | | |
| Example | DDT | (2,3-dimercaptopropyl) | — | 202 | 234 | — | 40 | 60 | — |
| 2 | | propionate | | | | | | | |
| Example | DDT | (2,3-dimercaptopropyl) | — | 202 | 234 | — | 60 | 40 | — |
| 3 | | propionate | | | | | | | |
| Example | DDT | Methyl dihydrolipoate | — | 202 | 223 | — | 40 | 60 | — |
| 4 | | | | | | | | | |
| Example | DDT | (2,3-dimercaptopropyl) | Oleic | 202 | 234 | 282 | 15 | 60 | 25 |
| 5 | | propionate | acid | | | | | | |
| Example | DDT | (2,3-dimercaptopropyl) | Oleic | 202 | 234 | 282 | 10 | 50 | 40 |
| 6 | | propionate | acid | | | | | | |
| Example | N-tetradecanoyl- | (2,3-dimercaptopropyl) | — | 498 | 234 | — | 20 | 80 | — |
| 7 | N-(2-mercapto- | propionate | | | | | | | |
| | ethyl)tetrade | | | | | | | | |
| | canamide | | | | | | | | |
| Example | DDT | N,N-didecyl-6,8- | — | 202 | 488 | — | 40 | 60 | — |
| 8 | | disulfanyloctanamide | | | | | | | |
| Example | DDT | (2,3-dimercaptopropyl) | — | 202 | 234 | — | 80 | 20 | — |
| 9 | | propionate | | | | | | | |
| Example | DDT | (2,3-dimercaptopropyl) | — | 202 | 234 | — | 10 | 90 | — |
| 10 | | propionate | | | | | | | |

| | | | | | | | Dispersion liquid | |
|---|---|---|---|---|---|---|---|---|
| | | | | | | | | Recalculated |
| | | | | | | | | as |
| | Semiconductor nanoparticle complex | | | | | | | semiconductor |
| | Ratio | | | Fluores- | Full | | | nanoparticle |
| | | (L I + | | cence | width | Heat | Disper- | mass |
| | L I/ | L II)/ | Total L/ | quantum | at half | resist- | sion | (% by |
| | L II | total L | QD | yield | maximum | ance | medium | mass) |
| Example | 0.25 | 1.0 | 0.23 | 82 | 37 | 96 | IBOA | 35 |
| 1 | | | | | | | | |
| Example | 0.67 | 1.0 | 0.27 | 86 | 37 | 97 | IBOA | 35 |
| 2 | | | | | | | | |
| Example | 1.50 | 1.0 | 0.33 | 84 | 37 | 96 | IBOA | 35 |
| 3 | | | | | | | | |
| Example | 0.67 | 1.0 | 0.28 | 78 | 38 | 96 | IBOA | 35 |
| 4 | | | | | | | | |
| Example | 0.25 | 0.8 | 0.32 | 81 | 38 | 96 | IBOA | 35 |
| 5 | | | | | | | | |
| Example | 0.20 | 0.5 | 0.35 | 78 | 38 | 88 | IBOA | 30 |
| 6 | | | | | | | | |
| Example | 0.25 | 1.0 | 0.46 | 75 | 38 | 94 | IBOA | 20 |
| 7 | | | | | | | | |
| Example | 0.67 | 1.0 | 0.65 | 76 | 38 | 93 | IBOA | 25 |
| 8 | | | | | | | | |
| Example | 4.00 | 1.0 | 0.42 | 83 | 38 | 89 | IBOA | 25 |
| 9 | | | | | | | | |
| Example | 0.11 | 1.0 | 0.22 | 84 | 39 | 88 | IBOA | 30 |
| 10 | | | | | | | | |

TABLE 1-2

| | Semiconductor nanoparticle complex | | | | | | | | |
|---|---|---|---|---|---|---|---|---|---|
| | Substance name | | | | | | | | |
| | Ligand I | Ligand II | | Molecular weight | | | Weight | | |
| | (L I) | (L II) | Other | L I | L II | Other | L I | L II | Other |
| Example | DDT | — | — | 202 | — | — | 100 | 0 | — |
| 11 | | | | | | | | | |
| Example | — | (2,3-dimercaptopropyl) | — | — | 234 | — | 0 | 100 | — |
| 12 | | propionate | | | | | | | |
| Example | DDT | Dodecenylsuccinic acid | — | 202 | 284 | — | 60 | 60 | — |
| 13 | | | | | | | | | |
| Example | Oleic acid | (2,3-dimercaptopropyl) | — | 282 | 234 | — | 40 | 60 | — |
| 14 | | propionate | | | | | | | |
| Example | Oleic acid | Dodecenylsuccinic acid | — | 282 | 284 | — | 40 | 60 | — |
| 15 | | | | | | | | | |
| Example | DDT | — | Oleic | 202 | — | 282 | 50 | — | 50 |
| 16 | | | acid | | | | | | |
| Example | 3,6,9,12- | (2,3-dimercaptopropyl) | — | 207 | 284 | — | 40 | 50 | — |
| 17 | Tetraoxadecanamine | propionate | | | | | | | |

| | | | | | | | Dispersion liquid | |
|---|---|---|---|---|---|---|---|---|
| | | | | | | | | Recalculated |
| | | | | | | | | as |
| | Semiconductor nanoparticle complex | | | | | | | semiconductor |
| | Ratio | | | Fluores- | Full | | | nanoparticle |
| | | (L I + | | cence | width | Heat | Disper- | mass |
| | L I/ | L II)/ | Total L/ | quantum | at half | resist- | sion | (% by |
| | L II | total L | QD | yield | maximum | ance | medium | mass) |
| Example | — | 1.0 | 0.50 | 84 | 39 | 86 | IBOA | 20 |
| 11 | | | | | | | | |
| Example | 0.00 | 1.0 | 0.21 | 85 | 38 | 86 | IBOA | 25 |
| 12 | | | | | | | | |
| Example | 0.67 | 1.0 | 0.32 | 76 | 40 | 80 | IBOA | 25 |
| 13 | | | | | | | | |
| Example | 0.67 | 1.0 | 0.35 | 75 | 38 | 83 | IBOA | 25 |
| 14 | | | | | | | | |
| Example | 0.67 | 1.0 | 0.35 | 78 | 39 | 75 | IBOA | 25 |
| 15 | | | | | | | | |
| Example | — | 0.5 | 0.63 | 80 | 38 | 75 | IBOA | 20 |
| 16 | | | | | | | | |
| Example | 0.67 | 1.0 | 0.28 | 62 | 41 | 47 | IBOA | 35 |
| 17 | | | | | | | | |

TABLE 2
Dispersibility test

| | Hex- | | | | Ace- | | Etha- |
|---|---|---|---|---|---|---|---|
| Solvent | ane | Octane | IBOA | PGMEA | tone | PGME | nol |
| SP value | 7.3 | 7.6 | 8.9 | 9.4 | 9.8 | 9.8 | 13.0 |
| Example 1 | no | no | yes | yes | yes | yes | yes |
| Example 2 | no | no | yes | yes | yes | no | no |
| Example 3 | yes | yes | yes | yes | yes | no | no |
| Example 4 | no | no | yes | yes | yes | no | no |
| Example 5 | no | no | yes | yes | yes | no | no |
| Example 6 | yes | yes | yes | yes | yes | no | no |
| Example 7 | yes | yes | yes | no | no | no | no |
| Example 8 | yes | yes | yes | no | no | no | no |
| Example 9 | yes | yes | yes | no | no | no | no |
| Example 10 | no | no | yes | yes | yes | yes | yes |
| Example 11 | yes | yes | yes | no | no | no | no |
| Example 12 | no | no | yes | yes | yes | yes | yes |
| Example 13 | yes | yes | yes | no | no | no | no |
| Example 14 | no | no | yes | yes | yes | no | no |
| Example 15 | yes | yes | yes | no | no | no | no |
| Example 16 | yes | yes | yes | no | no | no | no |
| Example 17 | no | no | yes | yes | yes | yes | yes |

1. A semiconductor nanoparticle complex in which two or more ligands including a ligand I and a ligand II are coordinated to a surface of a semiconductor nanoparticle, wherein the ligands comprise an organic group and a coordinating group, wherein
the ligand I has one mercapto group as the coordinating group, and the ligand
II has two or more mercapto groups as coordinating groups.

2. The semiconductor nanoparticle complex according to claim 1, wherein a mass ratio of the ligand I to the ligand II (ligand I/ligand II) is 0.2 to 1.5.

3. The semiconductor nanoparticle complex according to claim 1, wherein a mass ratio of ligands to the semiconductor nanoparticle (ligands/semiconductor nanoparticle) is 0.60 or less.

4. The semiconductor nanoparticle complex according to claim 1, wherein a molecular weight of the ligand is 600 or less.

5. The semiconductor nanoparticle complex according to claim 1, wherein a total mass fraction of the ligand I and the ligand II in the two or more ligands is 0.7 or more.

6. The semiconductor nanoparticle complex according to claim 1, wherein a carbon atom having one mercapto group and a carbon atom having another mercapto group in the ligand II are bonded by direct bond or through not more than 3 other carbon atoms.

7. The semiconductor nanoparticle complex according to claim 1, wherein the organic group of the ligand II is a divalent or higher hydrocarbon group having a substituent or a hetero atom.

8. The semiconductor nanoparticle complex according to claim 1, wherein the organic group of the ligand I is a monovalent hydrocarbon group having a substituent or a hetero atom.

9. The semiconductor nanoparticle complex according to claim 1, wherein the ligand I is an alkylthiol.

10. The semiconductor nanoparticle complex according to claim 1, wherein a fluorescence quantum yield of the semiconductor nanoparticle complex is 70% or more.

11. The semiconductor nanoparticle complex according to claim 1, wherein a full width at half maximum of an emission spectrum of the semiconductor nanoparticle complex is 40 nm or less.

12. The semiconductor nanoparticle complex according to claim 1, wherein the semiconductor nanoparticle includes In and P.

13. The semiconductor nanoparticle complex according to claim 1, wherein a surface composition of the semiconductor nanoparticle includes Zn.

14. The semiconductor nanoparticle complex according to claim 1, wherein when the semiconductor nanoparticle complex is heated in air at 180° C. for 5 h, a change between the fluorescence quantum yield before heating and the fluorescence quantum yield after heating is 10% or less.

15. A semiconductor nanoparticle complex composition in which the semiconductor nanoparticle complex according to claim 1 is dispersed in a dispersion medium, wherein the dispersion medium is a monomer or a prepolymer.

16. A semiconductor nanoparticle complex cured membrane in which the semiconductor nanoparticle complex according to claim 1 is dispersed in a polymer matrix.

17. A semiconductor nanoparticle complex dispersion liquid in which a semiconductor nanoparticle complex in which two or more ligands are coordinated to a surface of a semiconductor nanoparticle is dispersed in a dispersion medium, wherein the two or more ligands include a ligand I and a ligand II, each comprising an organic group and a coordinating group, wherein the ligand I has one mercapto group as the coordinating group, the ligand II has two or more mercapto groups as coordinating groups, and a mass ratio of the ligand I to the ligand II (ligand I/ligand II) is 0.2 to 1.5.

18. The semiconductor nanoparticle complex dispersion liquid according to claim 17, wherein the dispersion medium is an organic dispersion medium.

19. The semiconductor nanoparticle complex according to claim 1, wherein the ligand II is an amide or ester.

20. The semiconductor nanoparticle complex according to claim 1, wherein the each thiol group of ligand II is separated only by carbon atoms.
